(19) United States
(12) Patent Application Publication
(10) Pub. No.: US 2026/0198230 A1
(43) Pub. Date: Jul. 9, 2026

(54) SEMICONDUCTOR MEMORY DEVICE AND METHOD FOR FABRICATING THE SAME

(71) Applicant: TAIWAN SEMICONDUCTOR MANUFACTURING COMPANY LTD., HSINCHU (TW)

(72) Inventors: ZHI-REN XIAO, HSINCHU COUNTY (TW); NUO XU, SAN JOSE, CA (US); PO-SHENG LU, HSINCHU CITY (TW); ZHIQIANG WU, HSINCHU COUNTY (TW)

(21) Appl. No.: 19/012,957

(22) Filed: Jan. 8, 2025

(51) Int. Cl. H10N 50/85; G11C 11/16; H10N 50/01; H10N 50/10

(52) U.S. Cl. CPC H10N 50/85; H10N 50/01; H10N 50/10; G11C 11/161

(57) ABSTRACT

A semiconductor memory structure is provided. The semiconductor memory structure includes a bottom electrode, a base stack stacking on the bottom electrode along a first direction, a free layer stacking on the base stack along the first direction; a tantalum (Ta)-containing capping layer formed on the free layer; and a top electrode formed over the Ta-containing capping layer. The Ta-containing capping layer includes tantalum oxide with oxygen concentration gradually decreased from a bottom portion of the Ta-containing capping layer toward a middle portion of the Ta-containing capping layer, and also gradually decreased from a top portion of the Ta-containing capping layer toward a middle portion of the Ta-containing capping layer.

### BACKGROUND

Many modern-day electronic devices contain electronic memory. Electronic memory may be volatile memory or non-volatile memory. Non-volatile memory is able to store data in the absence of power, whereas volatile memory is not. Magnetic random-access memory (MRAM) is one promising candidate for next generation electronic memory due to advantages over current electronic memory. Compared to current non-volatile memory, such as flash random-access memory, MRAM typically is faster and has better endurance. Compared to current volatile memory, such as dynamic random-access memory (DRAM) and static random-access memory (SRAM), MRAM typically has similar performance and density, but lower power consumption.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a fragmentary cross-sectional view of a semiconductor memory structure in accordance with some embodiments of the present disclosure.

FIG. 2 is an enlarged cross-sectional view of a tantalum (Ta)-containing capping layer of the semiconductor memory structure shown in FIG. 1 in accordance with some embodiments of the present disclosure.

FIG. 3 illustrate a distribution of boron atoms in a free layer of a semiconductor memory structure in accordance with some embodiments of the present disclosure.

FIG. 4 is a plot showing activation energy E_{A} of (a) Ta, (b) TaO, (c) TaO₂ and (d) Ta₂O₅ and their oxygen concentration in accordance with some embodiments of the present disclosure.

FIG. 5 is a plot showing boron diffusion length of (a) Ta, (b) TaO, (c) TaO₂ and (d) Ta₂O₅ with different annealing times during annealing process at 400° C. in accordance with some embodiments of the present disclosure.

FIG. 6 is a distribution of atoms in a free layer of a semiconductor memory structure after performing an annealing process in accordance with some embodiments of the present disclosure.

FIG. 7 is a flowchart illustrating a method of fabricating a semiconductor memory structure in accordance with some embodiment of the present disclosure.

FIGS. 8A to 8I illustrate diagrammatic cross-sectional side views of some embodiments of a semiconductor memory structure at various stages of fabrication, according to the method of FIG. 7.

FIGS. 9A to 9F illustrate diagrammatic cross-sectional side views of some another embodiments of a semiconductor memory structure at various stages of fabrication, according to the method of FIG. 7.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

In many instances, MRAM structures are embedded in a metallization layer (e.g., an interconnect structure of a semiconductor die) prepared in a back-end-of-line (BEOL) operation, whereas transistors are fabricated in a front-end-of-line (FEOL) operation. The MRAM structures may be embedded in any position of the metallization layer over the transistors. Within an MRAM structure, a magnetic tunnel junction (MTJ) is a device that changes its resistive state based on the state of magnetic materials within the device.

For an MRAM technology, capping layer can be an effective knob to leverage memory performances, such as thermal stability, resistance-area product (RA) and so on. MgO is usually used as a capping layer formed on a free layer, but during annealing process, boron atom may leave the free layer and diffuse through the MgO capping layer. However, energy barrier of MgO is high, so it is likely that boron may reside in the free layer or in an interface between the free layer and the MgO capping layer, which may damage magnetic properties such as interfacial perpendicular magnetization anisotropy (iPMA), saturation magnetization (Ms) and so on.

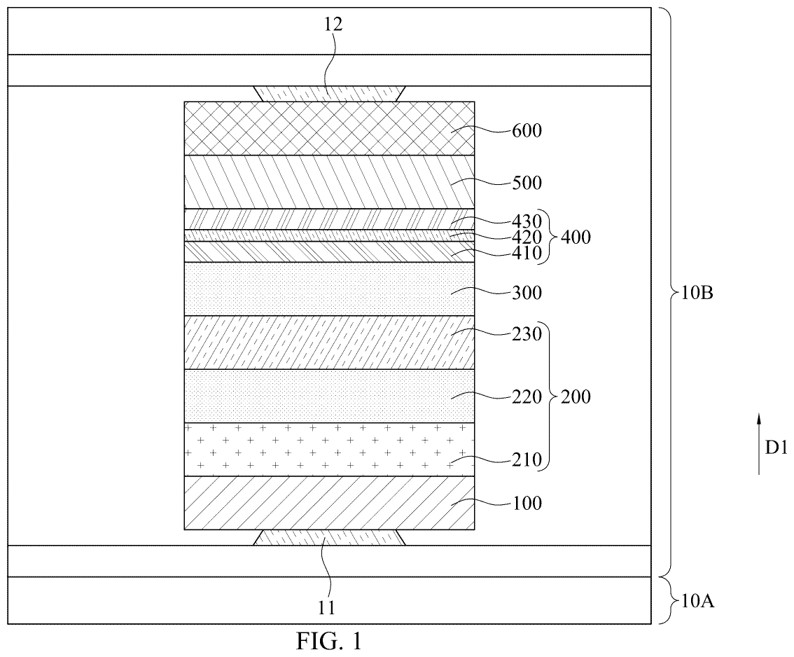

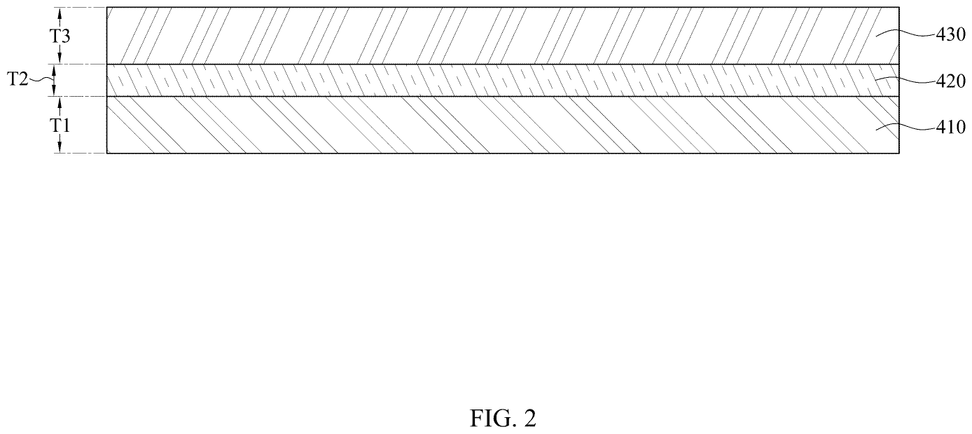

FIG. 1 illustrates a cross-sectional view of a semiconductor memory structure according to some embodiments of the present disclosure. The semiconductor memory structure is formed in a BEOL metallization stack 10B stacking on a FEOL stack 10A and includes a bottom electrode 100, a base stack 200, a free layer 300, a tantalum (Ta)-containing capping layer 400, a further capping layer 500 and a top electrode 600 stacking along a first direction D1.

The bottom electrode 100 may be electrically coupled to a first metallization layer (not shown) of the BEOL metallization stack 10B through a first via 11. The first via 11 may extend from the bottom electrode 100, through an etch stop layer, to the first metallization layer of the BEOL metallization stack 10B. The first via 11 may be a metal, such as copper, gold or tungsten. The bottom electrode 100 may be formed of a conductive material, such as, for example, titanium nitride, tantalum nitride, titanium (Ti), tantalum (Ta), ruthenium (Ru), platinum (Pt), tungsten (W), aluminum (Al), copper (Cu), or a combination of one or more of the foregoing. Further, a thickness of the bottom electrode 100 may be about 10 nm to about 100 nm. An exemplary formation method of the bottom electrode 100 includes physical vapor deposition (PVD) (such as sputtering), atomic layer deposition (ALD), e-beam or thermal evaporation, or the like.

The base stack 200 is disposed on the bottom electrode 100 and has a plurality of stacked layers, as shown in FIG. 1, including a seed layer 210, a reference layer 220 and a barrier layer 230.

The seed layer 210 is disposed on the bottom electrode 100 and may be a single layer or multilayer made of one or more metals or alloys that promote a uniform thickness in overlying layers and to maintain or enhance PMA, axis coercivity (Hc), and uniaxial anisotropy (Hk) in overlying magnetic layers. In some embodiments, as shown in FIG. 1, the seed layer 210 is a single layer and may comprise Ta, Zr, Nb, Ru, Mg, Sr, Ti, Al, V, Hf, B, Si, TaN, ZrN, NbN, NiCr, MgZr, MgNb, NiFeCr, or a combination thereof. In some alternative embodiments, the seed layer 210 is a composite (not shown) including, for example but not limited thereto, a lower layer made of one or more of Ta, Zr, Nb, TaN, ZrN, NbN, and Ru and an upper layer made of one or more of Mg, Sr, Ti, Al, V, Hf, B, Si, or an alloy of Mg with Zr or Nb. The lower layer of the seed layer 210 promotes a uniform thickness, (111) crystal structure, and smooth top surfaces in overlying layers. The (111) texture of upper layer of the seed layer 210 is advantageously used to induce a (111) texture in an overlying magnetic layer (e.g., the reference layer 220 as shown in FIG. 1). The seed layer 210 may be used to maintain or enhance PMA, Hc, and Hk in overlying free layer 300.

The reference layer 220 stacks on the seed layer 210. The reference layer 220 may be a ferromagnetic layer having a “fixed” magnetization direction. As an example, the magnetization direction of the reference layer 220 may be “up”, i.e. the first direction D1. In some embodiments, the reference layer 220 may have intrinsic PMA that is enhanced by contact with an appropriate seed layer along a bottom surface of the reference layer 220. In some embodiments, the reference layer 220 may include Co, CoFeB, or another alloy comprising two or more of Co, Fe, Ni, and B. In some embodiments, the reference layer 220 may be a multilayer structure represented by (Ni/Co)ₙ where n is the lamination number that is from 2 to 30, the Ni layer in the multilayer structure has a thickness of about 6 Angstroms, and the Co layer in the multilayer structure has a thickness of about 2.5 Angstroms. Optionally, Ni may be replaced by NiFe or NiCo, and Co may be replaced by CoFe in the laminated stack. In some embodiments, the reference layer 220 may be any face centered cubic (FCC) magnetic layer such as (Co/Pt)n, (Co/Pd)n, (Fe/Pt)n, or (Fe/Pd)n having PMA. The magnetic element may also include a transitional layer made of CoFeB, CoFe, or Co between the reference layer 220 and the barrier layer 230. In addition, the reference layer 220 may be modified to a synthetic anti-ferromagnetic (SAF) configuration, wherein a non-magnetic coupling layer such as Ru is sandwiched between two laminated (Ni/Co) stacks, for example.

The barrier layer 230 stacks on the reference layer 220 and is arranged abutting and between the free layer 300 and the reference layer 220. The barrier layer 230 provides electrical isolation between the free layer 300 and the reference layer 220, while still allowing electrons to tunnel through the barrier layer 230 under proper conditions. The barrier layer 230 may be a single layer including, for example, magnesium oxide (MgO), aluminum oxide (AlOₓ), titanium oxide (TiOₓ), zinc oxide (ZnO), or other metal oxides or metal nitrides. For example, the barrier layer 230 may be an amorphous barrier layer, such as AlOₓ layer or TiOₓ layer, or a crystalline barrier layer, such as MgO layer or a spinel (e.g., MgAl₂O₄) layer. Alternatively, the barrier layer 230 may be comprised of Cu or another high conductivity metal or metal alloy. Further, the barrier layer 230 is thin enough that a current through it can be established by quantum mechanical tunneling of conduction electrons. The thickness of the barrier layer 230 may have a thickness ranging from about 0.5 nanometers to about 2 nanometers.

The free layer 300 is formed on the barrier layer 230 of the base stack 200 and may be a single layer or composite wherein each layer is comprised of one or more of Co, Fe, and Ni. Furthermore, there may be a non-magnetic element such as boron (B) in the afore-mentioned single layer or composite free layer configuration. In some embodiments, the free layer 300 may be boron-containing materials before annealing, such as CoFeB, CoFeNiB, CoFeB/Ru/CoFe and the like, and the free layer 300 may be materials with decreased boron atoms or without boron atoms after annealing, such as CoFe, CoFeNi, CoFe/Ru. In some alternative embodiments, the bottom free layer 300 has a laminated structure comprised of a plurality of Co layers and antiferromagnetic (AF) coupling spacer layers formed in an alternating fashion similar to that of the reference layer configuration.

The Ta-containing capping layer 400 is formed on the free layer 300. For example, the Ta-containing capping layer 400 may include tantalum oxide (TaOx, 0<x≤2.5), such as TaO, TaO₂, Ta₂O₅ or a combination thereof. The Ta-containing capping layer 400 may be deposited by PVD, ALD, e-beam or thermal evaporation, or the like. The Ta-containing capping layer 400 comprises a bottom capping layer 410, a middle capping layer 420 and a top capping layer 430. The bottom capping layer 410 is formed on the free layer 300 and has a first thickness T1 and a first average oxygen concentration. The middle capping layer 420 is formed on the bottom capping layer 410 and has a second thickness T2 and a second average oxygen concentration. The top capping layer 430 is formed on the middle capping layer 420 and has a third thickness T3 and a third average oxygen concentration. In some embodiments, the first thickness T1 can be greater than the second thickness T2; and the third thickness T3 can be greater than the second thickness T2. In some embodiments, the first thickness T1 can be substantially identical to or greater than the third thickness T3. In some embodiments, a ratio of the first thickness T1 to the second thickness T2 may range from about 10:1 to about 10:9. In some embodiments, a ratio of the first thickness T1 to the second thickness T2 may range from about 5:1 to about 5:4. In some embodiments, a ratio of the third thickness T3 to the second thickness T2 may range from about 10:1 to about 10:9. In some embodiments, a ratio of the third thickness T3 to the second thickness T2 may range from about 5:1 to about 5:4. In some embodiments, a ratio of the first thickness to the third thickness may range from 3:1 to about 1:1. In some embodiments, the first thickness T1 may range from about 2 Å to about 5 Å. In some embodiments, the second thickness T2 may range from about 1 Å to about 3 Å. In some embodiments, the third thickness T3 may range from about 2 Å to about 5 Å.

The first average oxygen concentration may be higher than the second average oxygen concentration; and the third average oxygen concentration may be higher than the second average oxygen concentration. The first average oxygen concentration is gradually decreased from the bottom capping layer 410 near the free layer 300 toward the middle capping layer 420. The third average oxygen concentration is gradually decreased from the top capping layer 430 near the overlying further capping layer 500 toward the middle capping layer 420. The first average oxygen concentration may be equal to or more than about 75%; for example, about 80% to about 100%. The second average oxygen concentration may range from about 40% to about 80%; for example, about 40% to about 80%. The third average oxygen concentration may be equal to or more than about 75%; for example, about 80% to about 100%.

The further capping layer 500 may be applied onto the Ta-containing capping layer 400. The further capping layer 500, may include a metal-oxide or metal-nitride layer. The metal in the metal-oxide (or metal-nitride) capping layer includes beryllium (Be), magnesium (Mg), aluminum (Al), titanium (Ti), tungsten (W), germanium (Ge), platinum (Pt) and their alloy. Other elements may be chosen for the further capping layer 500. In some another embodiments, the further capping layer 500 may be a metal oxide to generate interfacial perpendicular anisotropy. According to one aspect of the present disclosure, the further capping layer 500 may be or include MgO layer.

The top electrode 600 is formed on the further capping layer 500 and may be electrically coupled to a second metallization layer (not shown) of the BEOL metallization stack 10B through a second via 12. The second via 12 may extend from the top electrode 600, through an inter-metal dielectric (IMD) layer (not shown), to a second metallization layer of the BEOL metallization stack 10B. The second via 12 may be a metal, such as copper, gold or tungsten. The top electrode 600 may be formed of a conductive material, such as, for example, titanium nitride, tantalum nitride, titanium (Ti), tantalum (Ta), ruthenium (Ru), platinum (Pt), tungsten (W), aluminum (Al), copper (Cu), or a combination of one or more of the foregoing. In some embodiments, the material of the top electrode 600 may be identical to or different from the material for the bottom electrode 100. Further, the top electrode 600 may be formed with a thickness of, for example, about 10 nm to about 100 nm. An exemplary formation method of the top electrode 600 includes PVD (such as sputtering), ALD, e-beam or thermal evaporation, or the like.

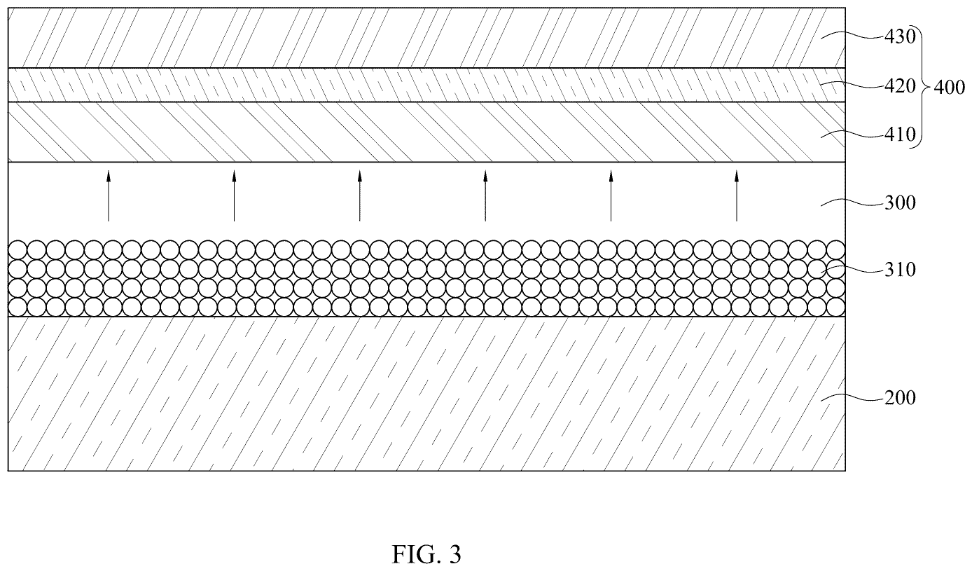

When using a MgO capping layer on a free layer (CoFeB), which serves as a comparative embodiment, due to MgO's high barrier energy resulting in poor diffusion of boron (B) atoms into MgO, so it is highly likely that boron atoms reside in the free layer or in the free layer/MgO interface during annealing process, strongly degrading Ms and iPMA. As shown in FIG. 3, due to the Ta-containing capping layer 400 formed on the free layer 300, the interface of the Ta-containing capping layer 400/free layer 300 (CoFeB) or the high oxygen concentration of the Ta-containing capping layer 400 (in particular, the bottom capping layer 410 which can be Ta₂O₅) allows for high boron diffusivity; therefore boron atom 310 may first cluster at free layer 300/base stack 200 interface (in particular, using MgO as the barrier layer 230) and then diffuse toward the Ta-containing capping layer 400 (a single direction as shown with arrows in FIG. 3) during annealing process. On the other hand, the middle capping layer 420 with a lower oxygen concentration (i.e., TaO₂ or TaO) can prevent too high resistance×area (RA) value. As the Ta-containing capping layer 400 is thicker, it is easier for boron atoms to sink at the free layer 300/base stack 200 interface before annealing process.

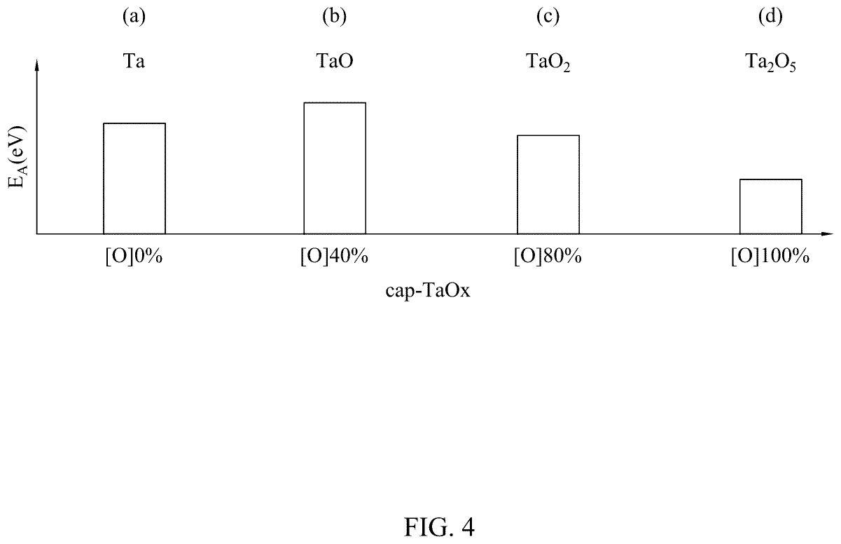

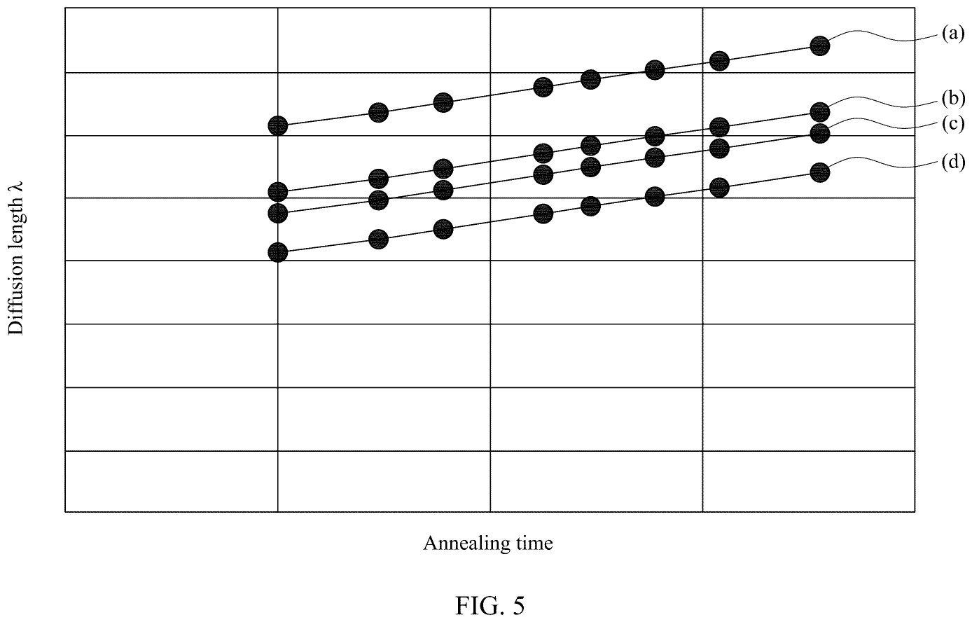

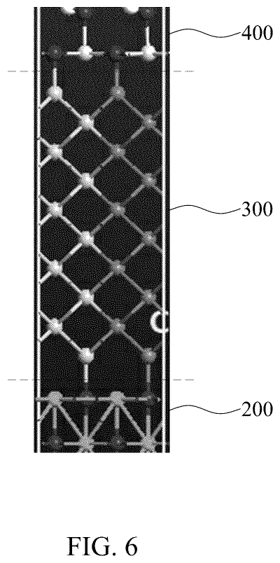

FIG. 4 shows activation energy E_{A} of (a) Ta, (b) TaO, (c) TaO₂ and (d) Ta₂O₅, respectively. For tantalum oxides (TaOx), while the oxygen concentration is higher, the activation energy is lower. Therefore, Ta₂O₅ is suitable for constituting the bottom capping layer 410 of the present disclosure, which allows faster boron diffusion during annealing process while TaO₂ or TaO are suitable for constituting the middle capping layer 420, which allows slower boron diffusion. Also, as shown in FIG. 5, it can be observed that during the same annealing time period, the boron diffusion length of (d) Ta₂O₅ is longer than that of TaO₂ or (b) TaO. Estimated diffusion length at 400° C. within 10 seconds may be higher than 1 mm for all TaOₓ, which is sufficient for boron to diffuse into the Ta-containing capping layer 400. Boron atom may diffuse out of the Ta-containing capping layer 400 under BEOL thermal budget, so that the free layer may become CoFe (i.e., without boron atoms) as shown in FIG. 6.

Since boron atoms diffuse in one way from the free layer 300 to the Ta-containing capping layer 400, recrystallization of the free layer 300 from one-side provides better crystalline and iPMA (Ks).

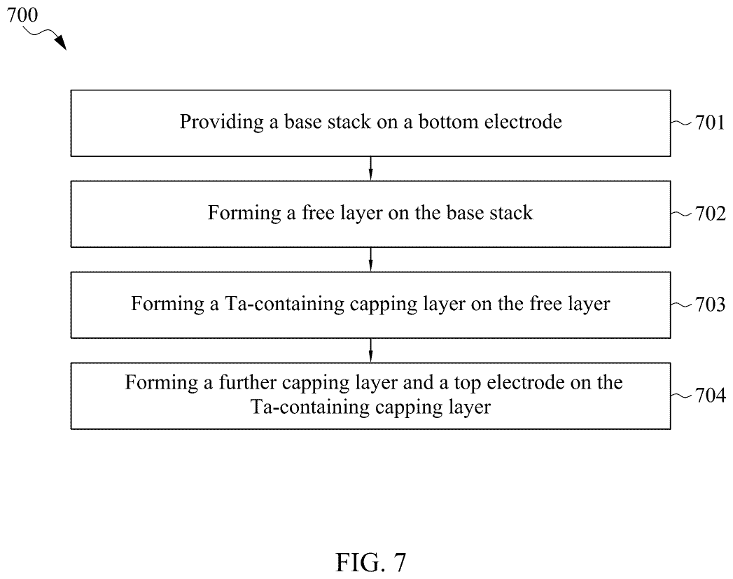

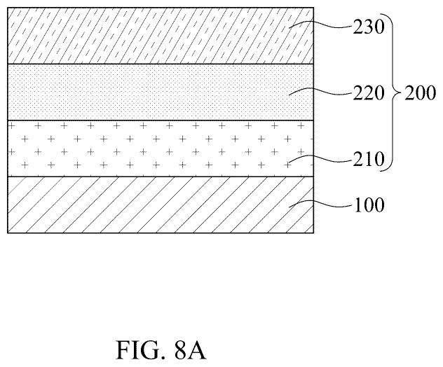

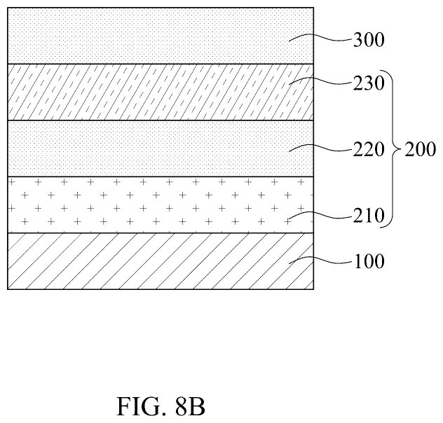

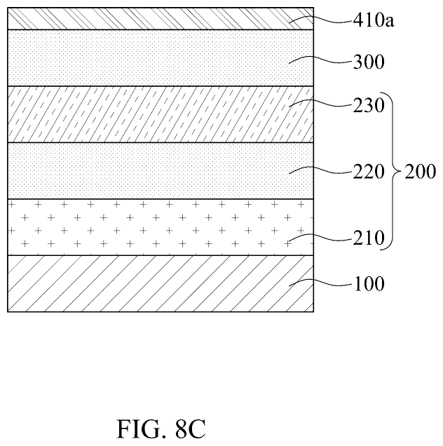

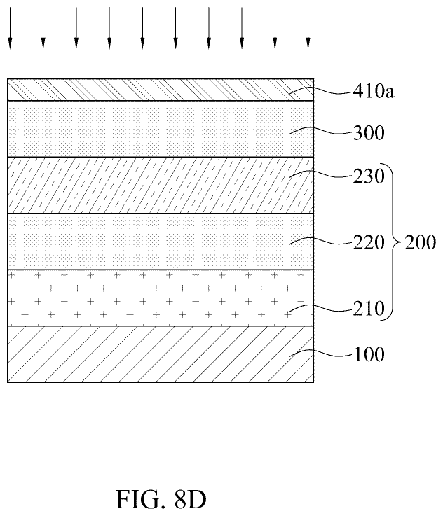

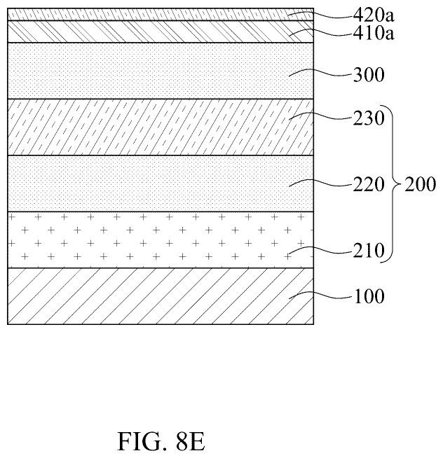

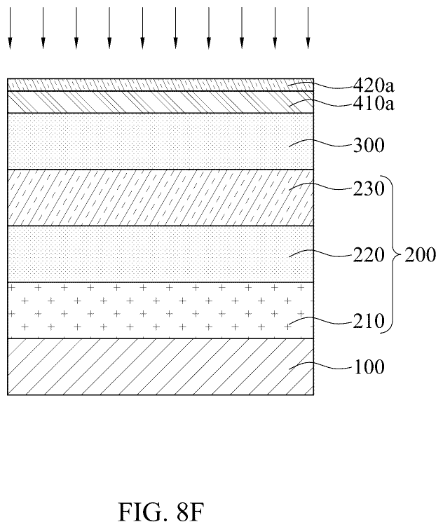

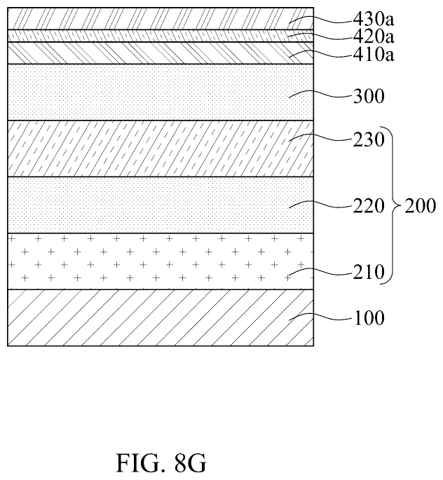

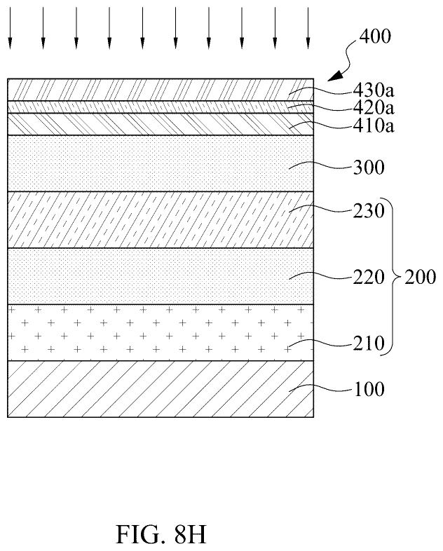

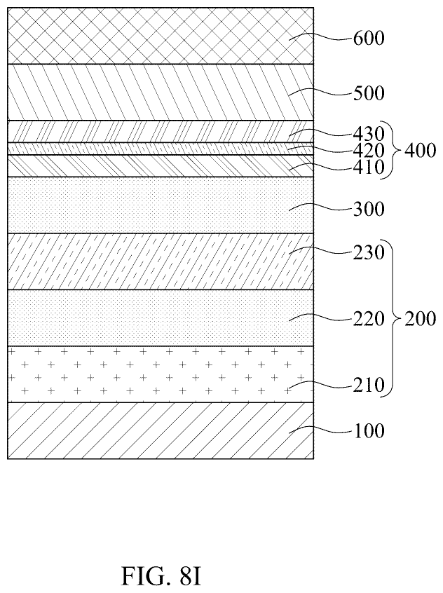

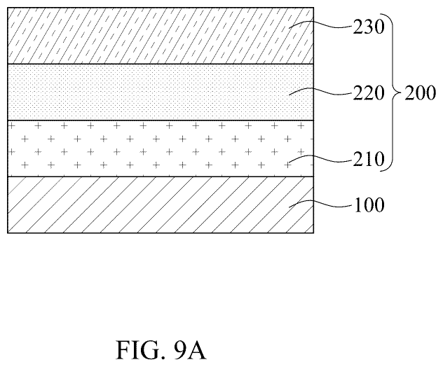

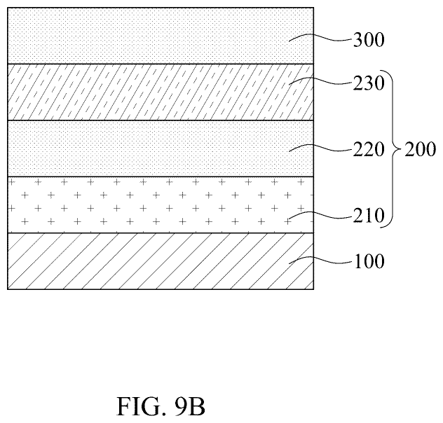

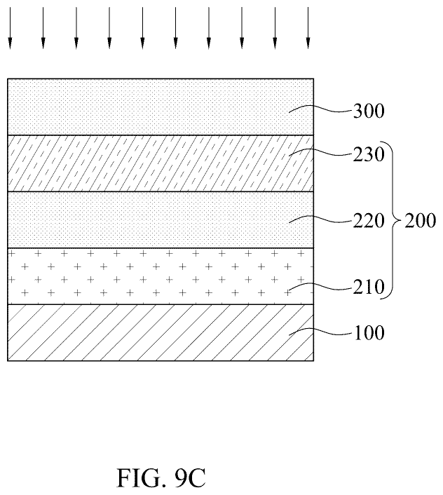

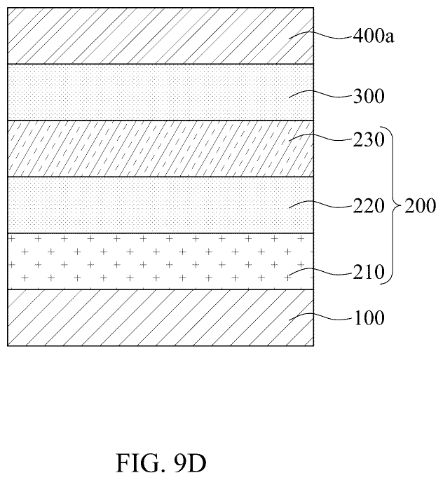

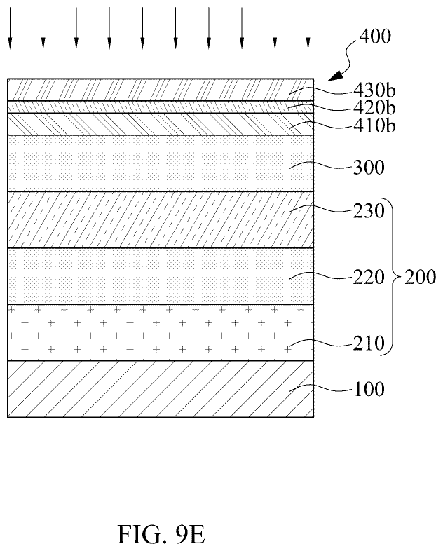

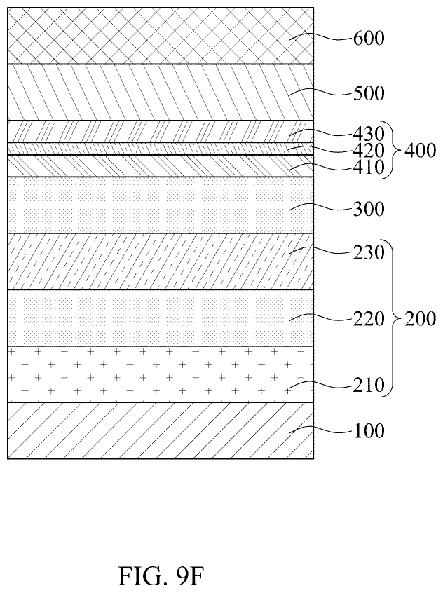

FIG. 7 is a flowchart representing a method 700 of manufacturing a semiconductor memory structure according to various aspects of the present disclosure in accordance with some embodiments. In some embodiments, the method 700 of manufacturing the semiconductor memory structure includes a number of operations (701, 702, 703 and 704). The method 700 of manufacturing the semiconductor memory structure will be further described according to one or more embodiments. It should be noted that the operations of the method 700 may be rearranged or otherwise modified within the scope of the various aspects. It should further be noted that additional processes may be provided before, during, and after the method 700, and that some other processes may be only briefly described herein. FIGS. 8A to 8I are diagrammatic perspective views illustrating various stages in the method 700 for forming the semiconductor memory structure according to aspects of one or more embodiments of the present disclosure. FIGS. 9A to 9F are diagrammatic perspective views illustrating various stages in the method 700 for forming the semiconductor memory structure according to aspects of some another embodiments of the present disclosure.

As shown in FIG. 8A, method 700 begins at operation 701 by providing a base stack 200 on a bottom electrode 100, in which the bottom electrode 100 is provided, and the base stack 200 including a seed layer 210, a reference layer 220 and a barrier layer 230 are sequentially deposited on the bottom electrode 100.

Method 700 continues with operation 702 as shown in FIG. 8B, in which a free layer 300 is formed on the base stack 200. In some embodiments, to form the free layer 300, two or more sublayers may be deposited over the base stack 200 and one or more spacer layers are formed between the sublayers so that every spacer layer is sandwiched by two sublayers. The free layer 300 may comprise boron-containing materials before annealing process, such as CoFeB, CoFeNiB and the like.

At operation 703, forming a Ta-containing capping layer 400 on the free layer 300 comprises depositing tantalum (Ta) on the free layer 300 to form a first Ta layer 410a as shown in FIG. 8C; performing a first oxidation process, which can be a natural oxidation or radical oxidation step as shown in FIG. 8D so that the first Ta layer 410a becomes an oxidized first Ta layer, which can become a bottom capping layer 410 after annealing; depositing tantalum (Ta) on the oxidized first Ta layer 410a to form a second Ta layer 420a as shown in FIG. 8E; performing a second oxidation process, which can be a natural oxidation or radical oxidation step as shown in FIG. 8F so that the second Ta layer 420a becomes an oxidized second Ta layer, which can become a middle capping layer 420 after annealing; depositing tantalum (Ta) on the oxidized second Ta layer 420a to form a third Ta layer 430a as shown in FIG. 8G; and performing a third oxidation process, which can be a natural oxidation or radical oxidation step as shown in FIG. 8H so that the third Ta layer 430a becomes an oxidized third Ta layer, which can become a top capping layer 430 after annealing.

The formation of the Ta-containing capping layer 400 may be performed in an oxidation chamber by applying an oxygen pressure of 10⁻⁶ Torr to 1 Torr for about 15 to 300 seconds. Oxygen pressure between 10⁻⁶ and 1 Torr may be applied for an oxidation time mentioned above when a resistance×area (RA) value is from about 0.5 to 5 ohm-μm². A mixture of O₂ with other inert gases such as Ar, Kr, or Xe may also be used for better control of the oxidation processes. In some embodiments, the first oxidation process is performed at a first flow rate at a first pressure; the second oxidation process is performed at a second flow rate at a second pressure; and the third oxidation process is performed at a third flow rate at a third pressure, wherein the second flow rate is lower than the first flow rate and is lower than the third flow rate and the second pressure is lower than the first pressure and is lower than the third pressure. In some embodiments, the first flow rate may be substantially identical or different from the third flow rate. In some embodiments, the first pressure may be substantially identical or different from the third pressure. The conditions of the Ta deposition and oxidation processes can be controlled so that a first thickness of the bottom capping layer 410 can be greater than a second thickness of the middle capping layer 420 and a third thickness of the top capping layer 430 can be greater than a second thickness of the middle capping layer 420. In some embodiments, the first thickness may range from about 2 Å to about 5 Å; the second thickness may range from about 1 Å to about 3 Å; and the third thickness may range from about 2 Å to about 5 Å.

In some embodiments, the Ta deposition and oxidation process may be repeated to form the Ta-containing capping layer 400 with higher oxygen concentration at bottom and top of the Ta-containing capping layer 400 while lower oxygen concentration in the middle of the Ta-containing capping layer 400.

At operation 704 as shown in FIG. 8I, a further capping layer 500 can be formed on the Ta-containing capping layer 400 through cyclic metal deposition and oxidation processes or a one-step metal sputtering with an oxygen pretreatment and an oxidation post-treatment; and a top electrode 600 is formed on the further capping layer 500 to complete an MTJ stack, and to continue the fabrication of the semiconductor memory structure in accordance with some embodiments.

The layers, including the seed layer 210, the reference layer 220 and the barrier layer 230 of the base stack 200, the free layer 300, the Ta-containing capping layer 400, the further capping layer 500 and the top electrode 600 form a MTJ structure. The layers in the MTJ structure described herein may be formed in a sputter deposition system such as an Anelva C-7100 thin film sputtering system or the like which typically includes three physical vapor deposition (PVD) chambers each having 5 targets, an oxidation chamber, and a sputter etching chamber. At least one of the PVD chambers is capable of co-sputtering. Typically, the sputter deposition process involves an argon sputter gas with ultra-high vacuum and the targets are made of metal or alloys. The layers of the MTJ structure may be formed after a single pump down of the sputter system to enhance throughput.

The MTJ structure can be annealed by applying a temperature between 300° C. and about 500° C. for a period of 30 minutes to 5 hours using an oven, or for only a few seconds when a rapid thermal anneal oven is employed. After annealing, the first Ta layer 410a turns into the bottom capping layer 410, the second Ta layer 420a turns into the middle capping layer 420, and the third Ta layer 430a turns into the top capping layer 430. The bottom capping layer 410 has a first average oxygen concentration, which may be equal to or more than about 75%; the middle capping layer 420 has a second average oxygen concentration, which may range from about 50% to about 75%; the top capping layer 430 has a third average oxygen concentration, which may be equal to or more than about 75%.

In some another embodiments, FIGS. 9A to 9F illustrate the method 700 for forming the semiconductor memory structure at various stages of fabrication, according to the method of FIG. 7. The operations 701 and 702 illustrated in FIGS. 9A and 9B are substantially identical or similar to those illustrated in FIGS. 8A and 8B; therefore those details are omitted in the interest of brevity.

At operation 703, forming a Ta-containing capping layer 400 on the free layer 300 comprises introducing oxygen plasma onto the free layer 300 as a pretreatment as shown in FIG. 9C; depositing a Ta layer 400a on the free layer 300; and performing oxidation process with controlled O₂/O₃ flow rate, oxidation time, oxygen partial pressure and so on, so that the Ta-containing capping layer 400 contains higher oxygen concentration at a bottom portion 410b and a top portion 430b of the Ta-containing capping layer 400 and a lower oxygen concentration at a middle portion 420b of the Ta-containing capping layer 400, as shown in FIGS. 9D and 9E.

At operation 704 as shown in FIG. 9F, a further capping layer 500 can be formed on the Ta-containing capping layer 400 through cyclic metal deposition and oxidation processes or a one-step metal sputtering with an oxygen pretreatment and an oxidation post-treatment; and a top electrode 600 is formed on the further capping layer 500 to complete an MTJ stack, and to continue the fabrication of the semiconductor memory structure in accordance with some embodiments.

The layers, including the seed layer 210, the reference layer 220 and the barrier layer 230 of the base stack 200, the free layer 300, the Ta-containing capping layer 400, the further capping layer 500 and the top electrode 600 form a MTJ structure. The layers in the MTJ structure described herein may be formed in a sputter deposition system such as an Anelva C-7100 thin film sputtering system or the like which typically includes three physical vapor deposition (PVD) chambers each having 5 targets, an oxidation chamber, and a sputter etching chamber. At least one of the PVD chambers is capable of co-sputtering. Typically, the sputter deposition process involves an argon sputter gas with ultra-high vacuum and the targets are made of metal or alloys. The layers of the MTJ structure may be formed after a single pump down of the sputter system to enhance throughput.

The MTJ structure may be annealed by applying a temperature between 300° C. and about 500° C. for a period of 30 minutes to 5 hours using an oven, or for only a few seconds when a rapid thermal anneal oven is employed. After annealing, the bottom portion 410b of the Ta-containing capping layer 400 turns into a bottom capping layer 410, the middle portion 420b of the Ta-containing capping layer 400 turns into a middle capping layer 420, and the top portion 430b of the Ta-containing capping layer 400 turns into the top capping layer 430. The bottom capping layer 410 has a first average oxygen concentration, which may be equal to or more than about 75%; the middle capping layer 420 has a second average oxygen concentration, which may range from about 50% to about 75%; the top capping layer 430 has a third average oxygen concentration, which may be equal to or more than about 75%.

To improve MRAM's interfacial Perpendicular Magnetization Anisotropy (iPMA) and magnetization (Ms), the Ta-containing capping layer 400 is formed on the free layer 300 so as to avoid boron clustering at an interface of the free layer 300 and the Ta-containing capping layer 400 because tantalum oxides (TaOx) have lower activation energy. Since boron atoms can diffuse from the free layer 300 toward the Ta-containing capping layer 400 and then out of the free layer 300 after annealing process, enhanced crystallinity of the free layer 300 results in improved MRAM's reliability.

In some embodiments, a semiconductor memory device of the present invention comprises a bottom electrode, a base stack stacking on the bottom electrode along a first direction, a free layer stacking on the base stack along the first direction; a tantalum (Ta)-containing capping layer formed on the free layer and comprising tantalum oxide with oxygen concentration gradually decreased from a bottom portion of the Ta-containing capping layer toward a middle portion of the Ta-containing capping layer, and also gradually decreased from a top portion of the Ta-containing capping layer toward the middle portion of the Ta-containing capping layer; and a top electrode formed over the Ta-containing capping layer.

In some embodiments, a magnetic tunnel junction (MTJ) structure of the present invention comprises a tantalum (Ta)-containing capping layer stacking on a free layer, wherein the Ta-containing capping layer comprises: a bottom capping layer formed on the free layer and comprising tantalum oxide with a first oxygen concentration; a middle capping layer formed on the bottom capping layer and comprising tantalum oxide with a second oxygen concentration; and a top capping layer formed on the middle capping layer and comprising tantalum oxide with a third oxygen concentration, wherein the middle capping layer is thinner than the bottom capping layer and the top capping layer, and wherein the first oxygen concentration is higher than the second oxygen concentration, and the third oxygen concentration is higher than the second oxygen concentration.

In some embodiments, a method for forming a semiconductor memory device of the present invention comprises forming a base stack on a bottom electrode including sequentially depositing a seed layer, a reference layer and a barrier layer; forming a boron-containing layer on the base stack; forming a tantalum (Ta)-containing capping layer on the boron-containing layer; and forming a further capping layer on the Ta-containing capping layer; and forming a top electrode on the further capping layer, wherein the Ta-containing capping layer comprises a middle portion with an oxygen concentration different from oxygen concentrations at a top portion and a bottom portion of the Ta-containing capping layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor memory structure, comprising
a bottom electrode,
a base stack stacking on the bottom electrode along a first direction,
a free layer stacking on the base stack along the first direction;
a tantalum (Ta)-containing capping layer formed on the free layer and comprising tantalum oxide with oxygen concentration gradually decreased from a bottom portion of the Ta-containing capping layer toward a middle portion of the Ta-containing capping layer, and also gradually decreased from a top portion of the Ta-containing capping layer toward the middle portion of the Ta-containing capping layer; and
a top electrode formed over the Ta-containing capping layer.

2. The semiconductor memory structure of claim 1, wherein an average oxygen concentration of the bottom portion of the Ta-containing capping layer is equal to or more than about 75%; an average oxygen concentration of the top portion of the Ta-containing capping layer is equal to or more than about 75%; and an average oxygen concentration of the middle portion of the Ta-containing capping layer ranges from about 40% to about 80%.

3. The semiconductor memory structure of claim 1, wherein the bottom portion of the Ta-containing capping layer has a first thickness; the middle portion of the Ta-containing capping layer has a second thickness; and the top portion of the Ta-containing capping layer has a third thickness, wherein a ratio of the first thickness to the second thickness and the third thickness range from about 10:1:10 to about 10:9:10.

4. The semiconductor memory structure of claim 1, wherein the bottom portion of the Ta-containing capping layer comprises Ta₂O₅; the middle portion of the Ta-containing capping layer comprises TaO₂ or TaO; and the top portion of the Ta-containing capping layer comprises Ta₂O₅.

5. The semiconductor memory structure of claim 1, further comprising a further capping layer formed on the Ta-containing capping layer and sandwiched by the Ta-containing capping layer and the top electrode.

6. The semiconductor memory structure of claim 1, wherein the base stack comprises:
a seed layer disposed over the bottom electrode;
a reference layer disposed over the seed layer; and
a barrier layer disposed over the reference layer, wherein the free layer is formed on the barrier layer.

7. The semiconductor memory structure of claim 6, wherein the barrier layer comprises MgO.

8. The semiconductor memory structure of claim 1, wherein the Ta-containing capping layer has a thickness ranging from about 5 Å to about 13 Å.

9. A magnetic tunnel junction (MTJ) structure, comprising:
a tantalum (Ta)-containing capping layer stacking on a free layer, wherein the Ta-containing capping layer comprises:
a bottom capping layer formed on the free layer and comprising tantalum oxide with a first oxygen concentration;
a middle capping layer formed on the bottom capping layer and comprising tantalum oxide with a second oxygen concentration; and
a top capping layer formed on the middle capping layer and comprising tantalum oxide with a third oxygen concentration,
wherein the middle capping layer is thinner than the bottom capping layer and the top capping layer, and
wherein the first oxygen concentration is higher than the second oxygen concentration, and the third oxygen concentration is higher than the second oxygen concentration.

10. The MTJ structure of claim 9, wherein the bottom capping layer has a first thickness; the middle capping layer has a second thickness; and the top capping layer has a third thickness, wherein a ratio of the first thickness to the second thickness and the third thickness range from about 10:1:10 to about 10:9:10.

11. The MTJ structure of claim 9, wherein the first oxygen concentration is equal to or more than about 80%; the third oxygen concentration is equal to or more than about 80%; and the second oxygen concentration ranges from about 0% to about 80%.

12. The MTJ structure of claim 9, wherein the first oxygen concentration is substantially identical to the third oxygen concentration; and a thickness of the bottom capping layer is substantially identical to a thickness of the top capping layer.

13. The MTJ structure of claim 9, wherein
the bottom capping layer comprises Ta₂O₅;
the middle capping layer comprises TaO₂ or TaO; and
the top capping layer comprises Ta₂O₅.

14. The MTJ structure of claim 9, wherein the free layer comprises CoFe.

15. A method of manufacturing a semiconductor memory structure, comprising:
forming a base stack on a bottom electrode including sequentially depositing a seed layer, a reference layer and a barrier layer;
forming a boron-containing layer on the base stack;
forming a tantalum (Ta)-containing capping layer on the boron-containing layer; and
forming a further capping layer on the Ta-containing capping layer; and
forming a top electrode on the further capping layer,
wherein the Ta-containing capping layer comprises a middle portion with an oxygen concentration different from oxygen concentrations at a top portion and a bottom portion of the Ta-containing capping layer.

16. The method of claim 15, wherein forming the Ta-containing capping layer comprises:
depositing tantalum on the boron-containing layer to form a first Ta layer;
performing a first oxidation process so that the first Ta layer becomes an oxidized first Ta layer;
depositing tantalum on the oxidized first Ta layer to form a second Ta layer;
performing a second oxidation process so that the second Ta layer becomes an oxidized second Ta layer;
depositing tantalum on the oxidized second Ta layer to form a third Ta layer; and
performing a third oxidation process so that the third Ta layer becomes an oxidized third Ta layer.

17. The method of claim 16, wherein the first oxidation process is performed at a first flow rate at a first pressure; the second oxidation process is performed at a second flow rate at a second pressure; and the third oxidation process is performed at a third flow rate at a third pressure, wherein the second flow rate is lower than the first flow rate and is lower than the third flow rate and the second pressure is lower than the first pressure and is lower than the third pressure.

18. The method of claim 16, further comprising performing annealing process after forming the top electrode,
wherein after annealing process, the oxidized first Ta layer turns into a bottom capping layer with a first oxygen concentration, the oxidized second Ta layer turns into a middle capping layer with a second oxygen concentration, and the oxidized third Ta layer turns into a top capping layer with a third oxygen concentration, and
wherein the first oxygen concentration is higher than the second oxygen concentration, and the third oxygen concentration is higher than the second oxygen concentration.

19. The method of claim 15, wherein forming the Ta-containing capping layer comprises:
introducing oxygen plasma onto the boron-containing layer;
depositing a Ta layer on the boron-containing layer; and
performing an oxidation process to oxydize the Ta layer to form the Ta-containing capping layer so that the Ta-containing capping layer contains higher oxygen concentration at a bottom portion and a top portion of the Ta-containing capping layer and a lower oxygen concentration at a middle portion of the Ta-containing capping layer.

20. The method of claim 19, further comprising performing an annealing process after forming the top electrode,
wherein after annealing process, the bottom portion of the Ta-containing capping layer turns into a bottom capping layer with a first oxygen concentration, the middle portion of the Ta-containing capping layer turns into a middle capping layer with a second oxygen concentration, and the top portion of the Ta-containing capping layer turns into a top capping layer with a third oxygen concentration, and
wherein the first oxygen concentration is higher than the second oxygen concentration, and the third oxygen concentration is higher than the second oxygen concentration.
